(19) United States
(12) Patent Application Publication
(10) Pub. No.: US 2025/0336838 A1
(43) Pub. Date: Oct. 30, 2025

(54) ELECTRONIC DEVICE AND METHOD FOR MANUFACTURING THE SAME

(71) Applicant: Innolux Corporation, Miaoli County (TW)

(72) Inventors: Kuang-Ming Fan, Miaoli County (TW); Jui-Kuo Lin, Miaoli County (TW)

(73) Assignee: Innolux Corporation, Miaoli County (TW)

(21) Appl. No.: 19/174,896

(22) Filed: Apr. 9, 2025

Related U.S. Application Data
(60) Provisional application No. 63/639,701, filed on Apr. 29, 2024.

(30) Foreign Application Priority Data
Sep. 27, 2024 (CN) 202411362136.7

(51) Int. Cl. H01L 23/538; H01L 21/48; H01L 21/66; H01L 23/00; H01L 23/13; H01L 23/14; H01L 23/498; H01L 25/065; H05K 1/18

(52) U.S. Cl. CPC H01L 23/5386; H01L 21/485; H01L 21/486; H01L 22/20; H01L 23/13; H01L 23/14; H01L 23/49866; H01L 23/5385; H01L 23/562; H01L 24/16; H01L 24/32; H01L 24/73; H01L 25/0655; H01L 2224/16227; H01L 2224/16238; H01L 2224/32225; H01L 2224/73204; H01L 2924/3512; H05K 1/181

(57) ABSTRACT

The present disclosure provides an electronic device and a method for manufacturing the same. The electronic device includes a first transparent substrate, a conductive element, a circuit structure, and an electronic unit. The first transparent substrate has a plurality of through holes. The conductive element is disposed in at least one of the plurality of through holes, wherein the conductive element includes a first portion and a second portion surrounded by the second portion. The circuit structure is disposed on the first transparent substrate. The electronic unit is disposed on the circuit structure and is electrically connected to the conductive element through the circuit structure. The surface of the first portion of the conductive element has a plurality of recesses, and at least one portion of the second portion of the conductive element is disposed in at least one of the plurality of recesses.

### CROSS-REFERENCE TO RELATED APPLICATION

This application claims the priority benefit of U.S. provisional application Ser. No. 63/639,701, filed on Apr. 29, 2024, and China application serial no. 202411362136.7, filed on Sep. 27, 2024. The entirety of each of the above-mentioned patent applications is hereby incorporated by reference herein and made a part of this specification.

### BACKGROUND

### Technical Field

The present disclosure relates to an electronic device and a method for manufacturing the same, and particularly relates to an electronic device with good reliability and a method for manufacturing the same.

### Description of Related Art

In current semiconductor packaging technology, mounting electronic units with different functions on the same substrate is one of means to improve the performance of electronic devices. However, as the sizes of the electronic devices continue to develop towards light, thin, short, and small aspects, and the user's requirements to the performances of the electronic devices continue to increase, the density of the electronic units mounted on the is increased as well. This results in a continuous increase in the aspect ratio of the conductive vias penetrating through the substrate, for example, the aspect ratio may be at least as high as 9 or above. As such, it may be hard for the conductive vias to meet the current or future requirements in terms of the reliability.

### SUMMARY

The present disclosure provides an electronic device and a method for manufacturing the same in which defect regions are identified from a plurality of through holes among which conductive elements formed therein have defects such as voids, and then a repair process is performed on the defect regions, so that the conductive elements are repaired to include a first portion and a second portion surrounded by the first portion, wherein a surface of the first portion has a plurality of protrusions and a plurality of recesses, and at least a portion of the second portion is disposed in at least one of the plurality of recesses. As such, the defects of the conductive elements in the defect regions can be repaired, so there are no negative effects on the resistivity of the conductive element caused by the defects, and thus the reliability of the electronic device can be improved.

According to an embodiment of the present disclosure, the electronic device includes a first transparent substrate, a conductive element, a circuit structure, and an electronic unit. The first transparent substrate has a plurality of through holes. The conductive element is disposed in at least one of the plurality of through holes, wherein the conductive element includes a first portion and a second portion, and the first portion surrounds the second portion. The circuit structure is disposed on the first transparent substrate. The electronic unit is disposed on the circuit structure and electrically connected to the conductive element through the circuit structure. A surface of the first portion of the conductive element has a plurality of protrusions and a plurality of recesses, and at least a portion of the second portion of the conductive element is disposed in at least one of the plurality of recesses.

According to an embodiment of the present disclosure, a method for manufacturing an electronic device includes following steps. A transparent substrate is provided. A plurality of through holes are formed in the transparent substrate. A conductive element is provided in at least one of the plurality of through holes, which comprises following step. A first portion of the conductive element in at least one of the plurality of through holes is provided. Identifying the first portion of the conductive element to obtain a result whether the first portion of the conductive element has a defect region. Checking the result and performing a treatment on the defect region if the result shows that the first portion of the conductive element has the defect region. Providing a second portion of the conductive element on the defect region to form the conductive element.

Based on the above, in the electronic device and the method for manufacturing the same in the embodiments of the present disclosure, the defect regions are identified from the through holes among which the conductive elements formed therein having defects such as voids, and then the repair process is performed on the defect regions, so that the conductive elements are repaired to include a first portion and a second portion surrounded by the first portion, wherein the surface of the first portion has protrusions and recesses, and at least a portion of the second portion is disposed in at least one of recesses. As such, the defects of the conductive elements in the defect regions can be repaired, so there are no negative effects on the resistivity of the conductive element caused by the defects, and thus the reliability of the electronic device can be improved.

To make the features and advantages of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a cross-sectional schematic view of an electronic device according to an embodiment of the present disclosure.

FIG. 2 is a cross-sectional schematic view of an electronic device according to another embodiment of the present disclosure.

FIG. 3 is a cross-sectional schematic view of an electronic device according to yet another embodiment of the present disclosure.

FIG. 4 is a cross-sectional schematic view of an electronic device according to still another embodiment of the present disclosure.

FIG. 5A to FIG. 5C are cross-sectional schematic views of a method for manufacturing an electronic device according to an embodiment of the present disclosure.

FIG. 6A and FIG. 6B are cross-sectional schematic views of a method for manufacturing an electronic device according to another embodiment of the present disclosure.

FIG. 7A to FIG. 7C are cross-sectional schematic views of a method for manufacturing an electronic device according to yet another embodiment of the present disclosure.

### DESCRIPTION OF THE EMBODIMENTS

The disclosure can be understood with reference to the following detailed description in conjunction with the accompanying drawings. It should be noted that, for ease of understanding by readers and for the concision of the illustration, a plurality of drawings in the disclosure only depict a part of the package structure, and certain elements in the drawings are not drawn according to actual scale. In addition, the number and size of each element in the drawings are for illustration only, and are not intended to limit the scope of the disclosure. For example, the relative sizes, thicknesses and positions of various layers, regions and/or structures may be reduced or enlarged for clarity.

Certain terms may be used throughout the disclosure and the claims to refer to specific elements. Those skilled in the art will understand that electronic device manufacturers may refer to the same elements by different names. The disclosure does not intend to distinguish between elements that have the same function but have different names. In the following description and claims, the words including “having” and “including” are open-ended words, and thus should be interpreted as meaning “including but not limited to.”

In this disclosure, “one element being disposed on another element” is used for convenience to describe the relative position between the element and the another element, and is not intended to limit the process steps or sequence of the element and the another element.

Directional terms mentioned herein, such as “up,” “down,” “front,” “rear,” “left,” “right,” and the like refer only to the directions of the drawings. Accordingly, the directional terms used are for illustration, and are not intended to limit the disclosure. It should be understood that when an element or film layer is referred to as being “disposed on” or “connected to” another element or film layer, the element or the film layer may be directly on or connected to the another element or film layer, or intervening elements or film layers may also be present in between (non-direct circumstances). In contrast, when an element or film layer is referred to as being “directly on” or “directly connected to” another element or film layer, no intervening elements or film layers are present in between. In addition, when the element or film layer is referred to as overlapping another element, the element or film layer at least partially overlaps the another element or film layer.

In the text, the terms “about,” “approximately,” “essentially,” or “substantially” usually implies that a value is within 10% of a given value or range, or within 5%, 3%, 2%, 1%, or 0.5% of a given value or range. In addition, the description “a given range from a first value to a second value” or “a given range between a first value and a second value” implies that the given range includes the first value, the second value, and other values in between.

In some embodiments of the disclosure, terms related to bonding and connection, such as “connection,” “interconnection,” and the like, unless otherwise specified, may mean that two structures are in direct contact, or may also mean that two structures are not in direct contact, in which there are other structures provided between these two structures. The terms related to bonding and connection may also include the case where both structures are movable, or both structures are fixed. Furthermore, the terms “electrically connected” or “coupled” includes any direct and indirect means of electrical connection.

In the embodiments provided later, the same or similar reference numerals are used to refer to the same or similar elements, and the descriptions will not be repeated. In addition, as long as the features of the various embodiments do not depart from or conflict with the spirit of the disclosure, the embodiments may be mixed and matched as desired. It is intended that the disclosure covers modifications and variations provided that they fall within the scope of the following claims and their equivalents. That is, in the following embodiments, technical features in several different embodiments may be replaced, reorganized, and mixed to complete other embodiments without departing from the spirit of the disclosure. Moreover, the terms such as “first” and “second” mentioned in the specification or the claims are only used to name different elements or to distinguish different embodiments or scopes, and are not intended to limit the upper or lower limit of the number of the elements, nor are they intended to limit the manufacturing order or disposition order of the elements.

In some embodiments of this disclosure, the thickness, length, and width may be obtained through a measurement using an optical microscope (OM). The thickness or the width may be obtained by measuring from a cross-sectional image in an electron microscope, but is not limited thereto.

In some embodiments of this disclosure, a surface roughness may be obtained by observing the surface undulations at an appropriate and consistent magnification through the electron microscope such as a scanning electron microscope (SEM) or a transmission electron microscope (TEM) and comparing the surface undulations per unit length (e.g., 10 μm). In some embodiments, the peak-to-valley of the surface undulation has a difference in distance by 0.15 μm to 1 μm. The appropriate magnification refers to a magnification that a roughness or an average roughness of at least one surface with at least 10 undulate peaks is observed in the field of view. Each of layers shown in the accompanying drawings of this disclosure may all have rough surfaces. It is worth noting that the rough surfaces of the aforementioned layers may refer to the high and low undulations presented in the cross-sectional view when observing the surfaces of each layer through the electron microscope.

The process of the electronic device in this disclosure may be, for example, applied in a wafer-level package (WLP) process or a panel-level package (PLP) process. The electronic device described in this disclosure may be applied to power modules, semiconductor package devices, display devices, light-emitting devices, backlight devices, antenna devices (e.g., liquid crystal antennas), sensing devices, testing devices, or tiled devices, but is not limited thereto. The electronic device includes a rollable electronic device or a flexible electronic device, but is not limited thereto. The display device may include, for example, liquid crystal, light emitting diode (LED), quantum dot (QD), fluorescence, phosphor, other suitable materials, or combinations thereof. The light emitting diode may include, for example, organic light emitting diode (OLED), micro-LED, mini-LED, or quantum dot light emitting diode (QLED, QDLED), but is not limited thereto. According to some embodiments, the electronic device may include a panel and/or a backlight module, and the panel may include a liquid crystal panel or other self-emitting panels, but is not limited thereto. A tiled device may be, for example, a display tiled device or an antenna tiled device, but is not limited thereto. It should be noted that the electronic device may be any arrangement and combination of the aforementioned, but is not limited thereto.

The exemplary embodiments of this disclosure are described in the following for example, and the same reference numerals used in the figures and descriptions are represented to the same or similar portions.

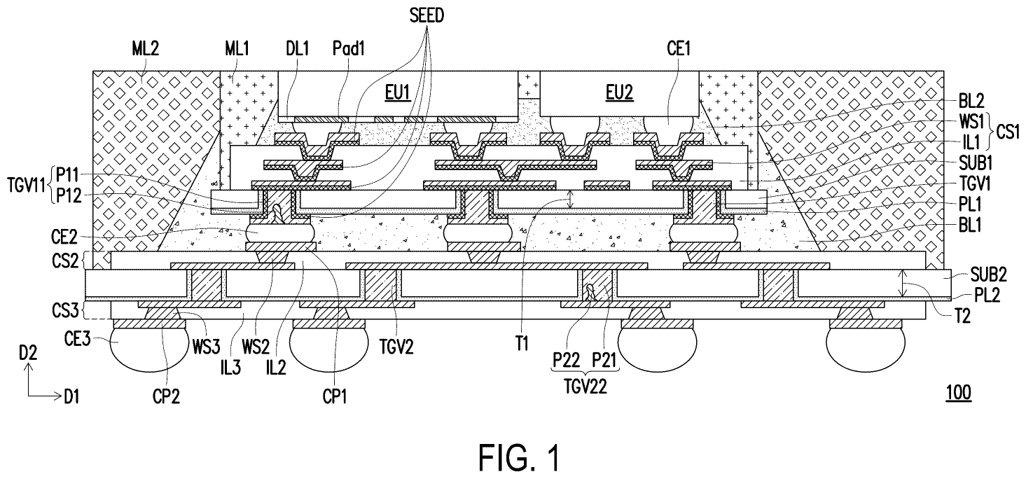

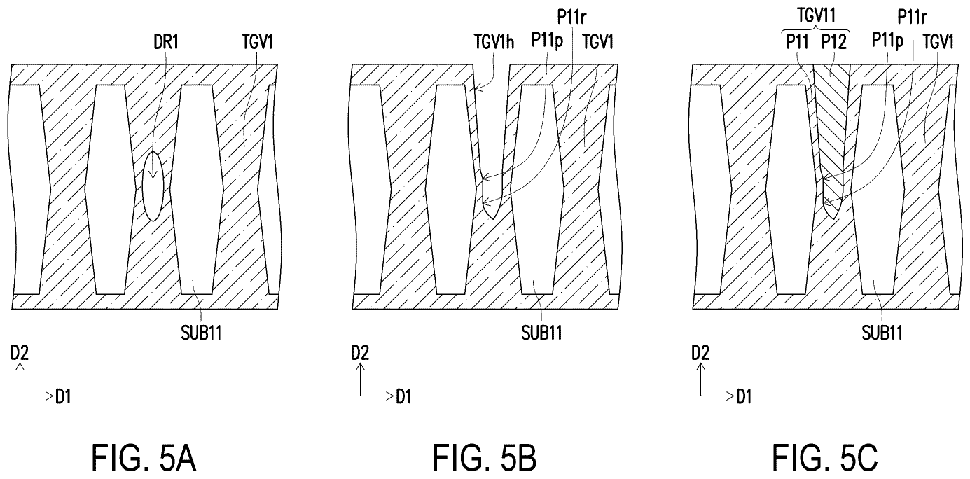

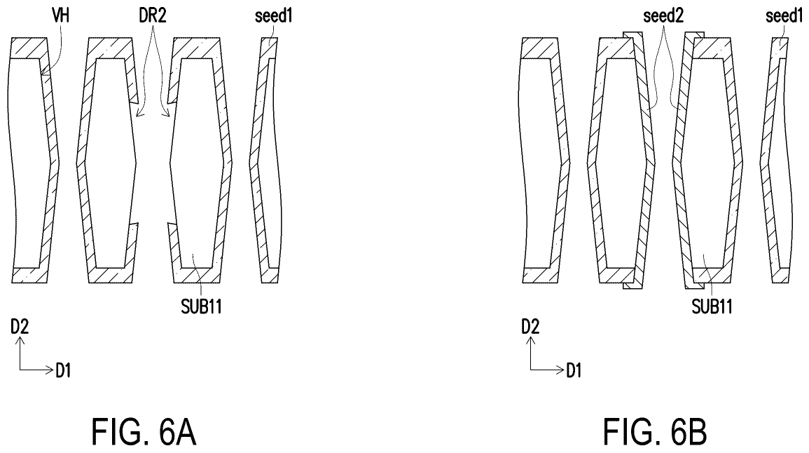

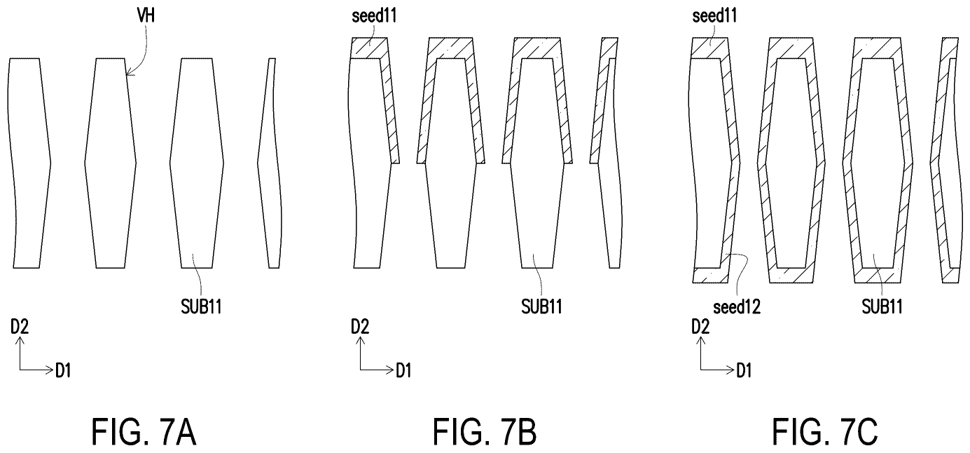

FIG. 1 is a cross-sectional schematic view of an electronic device according to an embodiment of the present disclosure. FIG. 5A to FIG. 5C are cross-sectional schematic views of a method for manufacturing an electronic device according to an embodiment of the present disclosure. FIG. 6A and FIG. 6B are cross-sectional schematic views of a method for manufacturing an electronic device according to another embodiment of the present disclosure. FIG. 7A to FIG. 7C are cross-sectional schematic views of a method for manufacturing an electronic device according to yet another embodiment of the present disclosure.

Referring to FIG. 1, an electronic device 100 may include a first transparent substrate SUB1, conductive elements TGV1, a circuit structure CS1, and an electronic unit EU1 or EU2.

The first transparent substrate SUB1 may have a plurality of through holes where the

conductive elements TGV1 are formed. The first transparent substrate SUB1 may include any suitable transparent substrate material, such as a glass substrate. In some embodiments, The through holes may be formed by performing a drilling process, an etching process, or a combination thereof on the first transparent substrate SUB1. For example, a laser drilling process may be performed on an upper surface and a lower surface of the first transparent substrate SUB1, respectively, so as to form the through holes, but is not limited thereto. In other embodiments, the through holes may also be formed in the first transparent substrate SUB1 through a modification treatment process (e.g., a laser modification process) and an etching process. According to some embodiments, the coefficient of thermal expansion of the transparent substrate which the disclosure is referred to may range from 2 ppm/° C. to 10 ppm/° C. According to some embodiments, the thickness of the transparent substrate which the disclosure is referred to may range from 30 μm to 1800 μm.

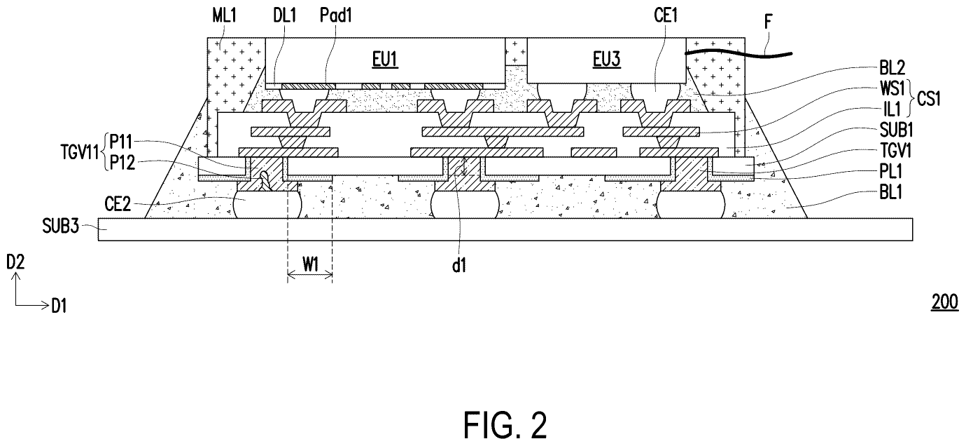

In some embodiments, the electronic device 100 may include a protective layer PL1 disposed on a surface of at least one of the plurality of through holes, or the protective layer PL1 covers at least a portion of a surface of the first transparent substrate SUB1. The protective layer PL1 may serve as a buffer layer and may be beneficial to improve the negative effects on the first transparent substrate SUB1 caused by the aforementioned process of forming the through holes. For example, the protective layer PL1 may repair defects (e.g., micro cracks) generated while the plurality of through holes in the first transparent substrate SUB1 are formed through the aforementioned modification treatment process (e.g., laser modification process) and etching process. In some embodiments, for examples, in the case where the first transparent substrate SUB1 is a glass substrate, the protective layer PL1 may mitigate the difference in the coefficient of thermal expansion (CTE) between the conductive elements TGV1 in the through holes and the first transparent substrate SUB1, thereby improving the adhesion of the conductive elements TGV1 formed in the through holes. In some embodiments, the protective layer PL1 may extend from the through holes to at least a portion of the upper surface or the lower surface of the first transparent substrate SUB1. According to some embodiments, referring to FIG. 2 together, the width W1 of the protective layer PL1 covering the surface of the first transparent substrate SUB1 may be greater than or equal to 0.5*the depth d1 of the through hole. Through this design, the protection for the first transparent substrate SUB1 may be enhanced, but is not limited thereto. In some embodiments, the toughness of the protective layer PL1 may be greater than or equal to 0.1 kJ/m² and less than or equal to 100 kJ/m². In this disclosure, the toughness of a film layer can be obtained by integrating the area under the stress-strain curve, and the stress-strain curve can be obtained by performing a tensile test on the film layer by using a universal testing machine. In other embodiments, the protective layer PL1 may completely cover the upper surface of the first transparent substrate SUB1, or completely cover the lower surface of the first transparent substrate SUB1, or completely cover both the upper surface and lower surface of the first transparent substrate SUB1, but this disclosure is not limited thereto.

The protective layer PL1 may include organic materials such as polyimide (PI), parylene, benzocyclobutene (BCB), epoxy resin, polycarbonate (PC), polyethylene terephthalate (PET), or polyethylene naphthalate (PEN).

In some embodiments, the conductive elements TGV1 may be formed through, for example, an electroplating process, an electroless plating process, a chemical vapor deposition (CVD) process, a sputtering process, an atomic layer deposition (ALD) process, a resistance heating evaporation process, an electron beam evaporation process, other suitable deposition methods, or combinations thereof. The conductive element TGV1 may include conductive materials such as metals, and may have a single-layer structure with a single type of metal or a composite layer structure with a plurality of sub-layers formed by different metals, wherein these sub-layers are stacked with each other. For examples, the conductive element TGV1 may have a composite layer structure including a titanium layer (not shown) and a copper layer (not shown) stacked on the titanium layer. In some embodiments, the conductive elements TGV1 may be formed through the following steps. First, seed layers SEED are formed on the surfaces of the through holes in the first transparent substrate SUB1, or on the protective layer PL1. For example, the seed layers SEED may include titanium, copper, tantalum, tungsten, nickel, gold, silver, chromium, gallium, nitrides, carbides, graphene, combinations thereof, or other suitable materials, but are not limited thereto. In other embodiments, the seed layers SEED may not be formed on the surfaces of the through holes, or may be formed on the surfaces of parts of the through holes, the present disclosure is not limited thereto. In some embodiments, the seed layers SEED may be formed through, for example, a CVD process, a sputtering process, an ALD process, other suitable deposition methods, or combinations thereof. Then, through the electroplating process, the electroless plating process, or other suitable methods, conductor layers are formed on the seed layers SEED, and thus the conductive elements TGV1 filling the through holes are formed. In some embodiments, the seed layers SEED may extend from the through holes to the upper surface or lower surface of the first transparent substrate SUB1. For example, the conductor layer may include copper, aluminum, graphene, combinations thereof, or other suitable materials, but is not limited thereto.

Among the conductive elements TGV1, a conductive element TGV11 disposed in at least one of the through holes may be included. The conductive element TGV11 may include a first portion P11 and a second portion P12, and the first portion P11 surrounds the second portion P12. In this embodiment, the conductive element TGV11 is a conductive element being identified as having a defect region (e.g., a region having defects such as voids) from the through holes and being subjected to a repair process to the defect region, so that the conductive element TGV11 is formed to include the first portion P11 and the second portion P12 surrounded by the first portion P11. As such, since the defects in the defect region of the conductive element has been repaired, so that the conductive element TGV11 is formed without negative effects on its resistivity, and thus the reliability of the electronic device 100 can be enhanced. In this embodiment, the description of “one element surrounding another element” may refer to the element being able to at least contact the side surface of the other element in the cross-sectional view. For example, as shown in FIG. 1, the first portion P11 may contact the side surface of the second portion P12. In other embodiments, the description of “one element surrounding another element” may refer to the element being adjacent to the side surface of another element in the cross-sectional view of the electronic device 100, but the present disclosure is not limited thereto.

In some embodiments, the conductive element TGV11 may be formed through the following steps included in the method of manufacturing the electronic device 100. First, as shown in FIG. 5A, a transparent substrate SUB 11 (corresponding to the first transparent substrate SUB1 or the second transparent substrate SUB2 shown in FIG. 1) is provided. Next, a plurality of through holes are formed in the transparent substrate SUB11. Then, a plurality of conductive elements TGV1 are formed in the plurality of through holes. Subsequently, a defect region DR1 is identified from the plurality of through holes among which the conductive elements TGV1 formed therein have defects such as voids. In some embodiments, a 3D X-ray may be used, for example, to identify the location of the conductive element TGV1 having the defect region DR1. Then, a treatment is performed on the defect region DR1. In some embodiments, as shown in FIG. 5B, a step of performing the treatment on the defect region DR1 may include removing at least a portion of the conductive element TGV1 formed in the through hole identified as having the defect region DR1 from the plurality of conductive elements TGV1, to form a repaired hole TGV1h. In some embodiments, a laser drill process, a mechanical drill process, an etching process, or a combination thereof may be used to remove at least the portion of the conductive element TGV1 to form the repaired hole TGV1h. In some embodiments, a laser with a wavelength of 266 nm to 1064 nm may be used for the laser drill process. Afterwards, as shown in FIG. 5C, another conductive element (corresponding to the second portion P12 of the conductive element TGV11 shown in FIG. 5C or FIG. 1) is formed on the defect region DR1. The conductive element (i.e., the first portion P11 of the conductive element TGV11) formed in the through hole identified as having the defect region DR1 among the plurality of conductive elements is electrically connected to the another conductive element (i.e., the second portion P12 of the conductive element TGV11). As such, the defects in the defect region DR1 of the conductive element TGV1 can be repaired, so that the conductive element TGV11 is formed to have a resistivity in which the negative effects caused by the defects are reduced, and thus the reliability of the electronic device 100 can be improved.

In some embodiments, the conductive element TGV11 in at least one of the plurality of through holes is provided by the following steps including: (1) providing a first portion of the conductive element TGV1 in at least one of the plurality of through holes; identifying the first portion of the conductive element TGV1 to obtain a result whether the first portion of the conductive element has a defect region DR1; checking the result and performing the treatment on the defect region DR1 if the result shows that the first portion of the conductive element TGV1 has the defect region DR1; and providing a second portion of the conductive element P12 on the defect region DR1 to form the conductive element TGV11. In some embodiments, the step of performing the treatment on the defect region DR1 includes removing at least a portion of the first portion of the conductive element TGV1 as the result shows that the first portion of the conductive element TGV1 has the defect region DR1. In some embodiment, the step of removing at least the portion of the first portion of the conductive element includes a laser drill process, a mechanical drill process, an etching process, or a combination thereof. In some embodiments, a surface of the first portion P11 of the conductive element TGV11 has a plurality of protrusions P11p and a plurality of recesses P11r in the case where at least the portion of the first portion of the conductive element has been removed, and the second portion P12 of the conductive element TGV11 is formed in at least one of the plurality of recesses P11r.

In this embodiment, the another conductive element (i.e., the second portion P12 of the conductive element TGV11 shown in FIG. 5C or FIG. 1) may be formed by filing a conductive material into the repaired hole TGV1h through any suitable method. For example, the second portion P12 of the conductive element TGV11 may be formed in the repaired hole TGV1h through a method such as an ink jet, the second portion P12 of the conductive element TGV11 may be formed by coating a conductive adhesive such as a silver paste or a copper paste onto the repaired hole TGV1h, or the second portion P12 of the conductive element TGV11 may be formed through depositing materials such as W(CO)₆ by using a laser chemical vapor deposition (LCVD) technology, and then subjecting a curing processes such as a laser sintering process or a curing process by using an infrared radiation (IR) lamp or an ultraviolet ray (UV) lamp. In this embodiment, the second portion P12 of the conductive element TGV11 may include a conductive material and an insulation material (e.g., a portion of the organic material being cured), wherein the proportion of the conductive material contacting the first portion P11 of the conductive element TGV11 is greater than the proportion of the insulation material contacting the first portion P11 of the conductive element TGV11. The proportion of one element contacting another element may be referred to a contact area between the one element and the another element, and therefore, the description of “the proportion of the conductive material contacting the first portion P11 of the conductive element TGV11 is greater than the proportion of the insulation material contacting the first portion P11 of the conductive element TGV11” may be referred to the contact area or the contact length of the conductive material contacting the first portion P11 is greater than the contact area or contact length of the insulation material contacting the first portion P11 in the conductive element TGV11. In this embodiment, the second portion P12 of the conductive element TGV11 includes a conductive material and an insulation material, and a proportion of the first portion P11 of the conductive element TGV11 contacting the conductive material is greater than a proportion of the first portion P11 of the conductive element TGV11 contacting the insulation material. In other embodiments, the second portion P12 of the conductive element TGV11 may also be formed through a process such as an electroplating process, a CVD process, a sputtering process, an ALD process, a resistance heating evaporation process, an electron beam evaporation process, other suitable deposition processes, or combinations thereof. For example, the first portion P11 of the conductive element TGV11 may be used as a seed layer, and the second portion P12 of the conductive element TGV11 filling the repaired hole TGV1h may be formed by growing the seed layer through an electroplating process. In this embodiment, the resistivity of the first portion P11 of the conductive element TGV11 may be different from the resistivity of the second portion P12 of the conductive element TGV11. In this embodiment, a ratio of the resistivity of the first portion P11 of the conductive element TGV11 to the resistivity of the second portion P12 of the conductive element TGV11 is in a range from 0.5 to 2 to decrease the risk of the electrically properties, but is not limited thereto.

In this embodiment, the first portion P11 of the conductive element TGV11 may include a surface with a plurality of protrusions and a plurality of recesses (e.g., protrusions P11p and recesses P11r shown in FIG. 5B or FIG. 5C), and at least a portion of the second portion P12 of the conductive element TGV11 may be disposed in at least one of the recesses of the surface of the first portion P11 of the conductive element TGV11. In this embodiment, the surface with a plurality of protrusions and a plurality of recesses may be formed, for example, by performing a treatment on the defect region DR1 by using a process such as a laser drill process, a mechanical drill process, an etching process, or a combination thereof. In this embodiment, the roughness of the surface with a plurality of protrusions and a plurality of recesses may be less than 1 μm.

In some embodiments, the step of identifying the defect region DR1 from a plurality of through holes may be conducted after forming the seed layer for the conductive element TGV1. For example, as shown in FIG. 6A and FIG. 6B, the method for manufacturing the electronic device 100 may include the following steps. First, as shown in FIG. 6A, a transparent substrate

SUB11 (corresponding to the first transparent substrate SUB1 or the second transparent substrate SUB2 shown in FIG. 1) is provided. Then, a plurality of through holes VH are formed in the transparent substrate SUB11. Subsequently, seed layers seed1 are formed in the plurality of through holes VH. Afterwards, a defect region DR2 is identified from the plurality of through holes VH. In some embodiments, the position of the seed layer seed1 having the defect region DR2 (e.g., the position where the seed layer seed1 has a defect of disconnection in the defect region DR2) may be identified by using, for example, a 3D X-ray or an optical coherence tomography (OCT). Then, a treatment is performed on the defect region DR2, so that the seed layer formed in the through hole VH is formed to be a continuous film layer in the defect region DR2. In this embodiment, as shown in FIG. 6B, seed layers seed2 may be formed in the through hole VH where the defect region DR2 is presented, so as to repair the defects of the seed layers seed1 in the defect region DR2. As such, the seed layer formed in the through hole VH is formed to be a continuous film layer in the defect region DR2. In this way, in the subsequent processes, the conductive elements being capable of well filling the plurality of through holes VH may be formed by growing the seed layers through an electroplating process. In other words, after the defect region DR2 is repaired by the seed layers seed2, the conductive elements are formed to be capable of well filling the plurality of through holes VH without voids generated as illustrated in FIG. 5A, and thereby reducing the probability of negative effects to the resistivity of the conductive elements and improving the reliability of the electronic device 100. In some embodiments, the seed layers seed2 may extend from the plurality of through holes VH to the upper surface or the lower surface of the transparent substrate SUB11.

In this embodiment, the seed layers seed2 may be formed by any suitable ways. For example, the seed layers seed2 may be formed in the through holes VH where the defect region DR2 is presented by a method such as an ink jet, the seed layers seed2 may be formed by coating a conductive adhesive such as a silver paste or a copper paste onto the through holes VH where the defect region DR2 is presented, or the seed layers seed2 may be formed through depositing materials such as W(CO)₆ by using a laser chemical vapor deposition (LCVD) technology, and then subjecting a curing processes such as a laser sintering process or a curing process by using an infrared radiation (IR) lamp or an ultraviolet ray (UV) lamp. In this embodiment, the seed layers seed2 may be formed by using a material having a viscosity coefficient in a range of 5 mPa·S to 1000 mPa·S, so that the seed layers seed2 can be well attached to the surfaces of the through holes VH. In other embodiments, the seed layers seed2 may also be formed through a process such as an electroplating process, a CVD process, a sputtering process, an ALD process, a resistance heating evaporation process, an electron beam evaporation process, other suitable deposition processes, or combinations thereof.

In some alternative embodiments, as shown in FIG. 7A to FIG. 7C, the method for manufacturing the electronic device 100 may include the following steps. First, as shown in FIG. 7A, a transparent substrate SUB11 (corresponding to the first transparent substrate SUB1 or the second transparent substrate SUB2 shown in FIG. 1) is provided. Then, a plurality of through holes VH are formed in the transparent substrate SUB11. Subsequently, seed layers seed11 are formed in the plurality of through holes VH, where the seed layers seed11 fill into the through holes VH from the upper surface of the transparent substrate SUB11, and ones of the ends of the seed layers seed11 formed in the through holes VH are located at the centers of the through holes VH (the centers are relative to the center position of the transparent substrate SUB11 in the thickness direction (e.g., direction D2)). Afterwards, seed layers seed12 are formed in the plurality of through holes VH, where the seed layers seed12 fill into the through holes VH from the lower surface of the transparent substrate SUB11, and ones of the ends of the seed layers seed12 formed in the through holes VH are located at the centers of the through holes VH and in contact with the seed layers seed11, so that continuous seed layers are formed in the through holes VH. As such, in the subsequent process, the conductive elements being capable of well filling the plurality of through holes VH may be formed by growing the seed layers through an electroplating process, and thereby improving the reliability of the electronic device 100. In this embodiment, after forming the seed layers seed11, the seed layers seed12 may be formed in the through holes VH of the transparent substrate SUB11 by flipping the upper and lower surfaces of the transparent substrate SUB11.

In this embodiment, any suitable method may be used to form the seed layers seed11 and the seed layers seed12. For example, the seed layers seed11 and the seed layers seed12 may be formed in the through holes VH by a method such as an ink jet, the seed layers seed11 and the seed layers seed12 may be formed by applying a conductive adhesive such as a silver paste or a copper paste in the through holes VH, or the seed layers seed11 and the seed layers seed12 may be formed by depositing materials such as W(CO)₆ using laser chemical vapor deposition (LCVD) technology, and then subjecting a curing processes such as a laser sintering process or a curing process by using an infrared radiation (IR) lamp or an ultraviolet ray (UV) lamp. In other embodiments, the seed layers seed11 and the seed layers seed12 may also be formed by a method such as an electroplating process, a CVD process, a sputtering process, an ALD process, a resistance heating evaporation process, an electron beam evaporation process, other suitable deposition processes, or combinations thereof. In some embodiments, the seed layers seed11 and the seed layers seed12 may serve as buffer layers to be beneficial to mitigate the negative effects on the transparent substrate SUB11 caused by the aforementioned process of forming the plurality of through holes VH. For example, the buffer layers may repair defects (such as micro cracks) generated while the plurality of through holes VH in the transparent substrate SUB11 are formed through the modification treatment processes (e.g., the laser modification processes) and etching processes. In some embodiments, for examples, in the case where the transparent substrate SUB11 is a glass substrate, the buffer layers may reduce the difference in coefficient of thermal expansion (CTE) between the transparent substrate SUB11 and the conductive elements formed in the plurality of through holes VH, thereby improving the adhesion of the conductive elements formed in the plurality of through holes VH.

Next, returning to FIG. 1, the circuit structure CS1 of the electronic device 100 may be disposed on the first transparent substrate SUB1. The circuit structure CS1 may include an insulation layer IL1 formed on the first transparent substrate SUB1 and a wiring structure WS1 formed in the insulation layer IL1. The insulation layer IL1 may include a plurality of insulation layers alternately stacked along the direction D2. The wiring structure WS1 may include a plurality of conductive patterns formed in the insulation layer IL1 and alternately stacked along the direction D2, and a conductive via connecting the conductive patterns. According to some embodiments, the ratio of the toughness of the protective layer PL1 to the toughness of the dielectric layer (such as the insulation layer IL1) of the circuit structure CS1 may be greater than or equal to 0.1 and less than or equal to 10. As such, the protective layer PL1 may effectively utilize the strain to release internal stress generated by heat or other processes, thereby enhancing the structural strength of the first transparent substrate SUB1 or reducing the generation of cracks in the first transparent substrate SUB1.

The wiring structure WS1 may include any suitable conductive material, or the conductive material may be composed of stacked seed layers SEED or conductive layers, such as copper, titanium, nickel, combinations thereof or alloys of the above materials, but is not limited thereto. The insulation layer IL1 may include organic materials or inorganic materials. The organic materials may include polyimide (PI), poly-p-xylylene (also known as Parylene), benzocyclobutene (BCB), epoxy, polycarbonate (PC), polyethylene terephthalate (PET), polyethylene naphthalate (PEN), polymers or other suitable organic materials, but are not limited thereto. The inorganic materials may include silicon oxide, silicon nitride, silicon oxynitride or other suitable inorganic materials, but are not limited thereto.

The electronic unit EU1 or EU2 of the electronic device 100 is disposed on the circuit structure CS1 and electrically connected to the conductive elements TGV11 and TGV1 through the circuit structure CS1. The electronic unit EU1 or EU2 may include a chip, a diode, an antenna unit, a memory unit, a photonic integrated circuit (PIC) unit, a sensor or a structure related to the semiconductor processes. In some embodiments, the electronic unit EU1 may include a pad Pad1, where the pad Pad1 may be located on one side of the electronic unit EU1. In the embodiments where the electronic unit is a chip, the side at which the pad Pad1 is disposed is the front side of the chip (also known as the active surface), while another side (or surface) opposite to the front side (or active surface) of the chip is the back side (or back surface). In this embodiment, the electronic unit EU1 may include a dielectric layer DL1 formed on the front side of the chip and surrounding the pad Pad1. The dielectric layer DL1 may include any suitable dielectric material. In this embodiment, the electronic unit EU1 may be different from the electronic unit EU2. In this embodiment, the amount of the pads Pad1 in different electronic units EU1 may be the same as or different from each other. According to some embodiments, the sizes of the pads Pad1 in different electronic units EU1 may be the same as or different from each other. The pads Pad1 may include any suitable conductive material, such as copper (Cu), aluminum (Al), nickel (Ni), molybdenum (Mo), titanium (Ti), alloys or combinations of the above materials, or other suitable materials, but is not limited thereto.

In some embodiments, the electronic device 100 may include a connection member CE1 disposed between the electronic unit EU1 or EU2 and the circuit structure CS1. The electronic unit EU1 or EU2 may be electrically connected to the circuit structure CS1 through the connection member CE1. In some embodiments, the connection member CE1 may include solder balls. In some embodiments, the material of the connection member CE1 may include tin-silver (SnAg), tin, silver, nickel, gold, copper, conductive paste, or other suitable conductive materials, but is not limited thereto.

In some embodiments, the electronic device 100 may include a second transparent substrate SUB2, where the first transparent substrate SUB1 may be bonded to the second transparent substrate SUB2 through a plurality of connection members CE2. In some embodiments, the second portion P12 of the conductive element TGV11 contacts one of the plurality of connection members CE2. In some embodiments, the thickness T2 of the second transparent substrate SUB2 may be greater than the thickness T1 of the first transparent substrate SUB1 for better support, but not limited thereto. The second transparent substrate SUB2 may have a plurality of through holes formed therein with conductive elements TGV2. The second transparent substrate SUB2 may include any suitable transparent substrate material, such as glass substrate. In some embodiments, the plurality of through holes may be formed by conducting a drill process, an etching process, or a combination thereof on the second transparent substrate SUB2. For example, a laser drill process may be conducted on the upper surface and lower surface of the second transparent substrate SUB2, respectively, to form the plurality of through holes, but is not limited thereto. In other embodiments, the plurality of through holes may also be formed in the second transparent substrate SUB2 through a modification treatment process (such as a laser modification process) and an etching process. The connection member CE2 may include solder balls. In some embodiments, the material of the connection member CE2 may include tin-silver (SnAg), tin, silver, nickel, gold, copper, conductive paste, or other suitable conductive materials, but is not limited thereto.

In some embodiments, the electronic device 100 may include a protective layer PL2 disposed on the surface of the plurality of through holes in the second transparent substrate SUB2. The protective layer PL2 may serve as a buffer layer to be beneficial to improve the negative effects on the second transparent substrate SUB2 caused by the process of forming the plurality of through holes. For example, the protective layer PL2 may repair defects (such as micro cracks) generated while the plurality of through holes in the second transparent substrate SUB2 are formed through the modification treatment process (such as the laser modification process) and the etching process. In some embodiments, for example, in the case where the second transparent substrate SUB2 is a glass substrate, the protective layer PL2 may mitigate the difference in coefficient of thermal expansion (CTE) between the conductive elements TGV2 in the plurality of through holes and the second transparent substrate SUB2, to improve the adhesion of the conductive elements TGV2 formed in the plurality of through holes. In some embodiments, the protective layer PL2 may extend from the plurality of through holes to the upper surface or lower surface of the second transparent substrate SUB2.

The protective layer PL2 may include organic materials such as polyimide (PI), parylene, benzocyclobutene (BCB), epoxy resin, polycarbonate (PC), polyethylene terephthalate (PET) or polyethylene naphthalate (PEN).

In some embodiments, the conductive elements TGV2 may be formed through, for example, an electroplating process, an electroless plating process, a chemical vapor deposition (CVD) process, a sputtering process, an atomic layer deposition (ALD) process, a resistance heating evaporation process, an electron beam evaporation process, other suitable deposition methods, or combinations thereof. The conductive elements TGV2 may include conductive materials such as metals, and may have, for example, a single-layer structure with a single type of metal or a composite layer structure with a plurality of sub-layers formed by different metals, wherein these sub-layers are stacked with each other. For examples, the conductive elements TGV2 may include a titanium layer (not shown) and a copper layer (not shown) stacked on the titanium layer, so as to have the composite layer structure. In some embodiments, the conductive elements TGV2 may be formed through the following steps. First, seed layers (not shown) are formed on the surfaces of the plurality of through holes in the second transparent substrate SUB2. In some embodiments, the seed layers may be formed through a process such as a CVD process, a sputtering process, an ALD process, other suitable deposition methods, or combinations thereof. Then, through an electroplating process, the seed layer is grown to form the conductive elements TGV2 filling the plurality of through holes. In some embodiments, the seed layer may extend from the plurality of through holes to the upper surface or lower surface of the second transparent substrate SUB2.

Among the conductive elements TGV2, a conductive element TGV22 disposed in at least one of the through holes may be included. The conductive element TGV22 may include a first portion P21 and a second portion P22, and the first portion P21 surrounds the second portion P22. In this embodiment, the conductive element TGV22 is a conductive element being identified as having a defect region (e.g., a region having defects such as voids) from the through holes and being subjected to a repair process to the defect region, so that the conductive element TGV22 is formed to include the first portion P21 and the second portion P22 surrounded by the first portion P21. As such, since the defects in the defect region of the conductive element has been repaired, so that the conductive element TGV22 is formed without negative effects on its resistivity, and thus the reliability of the electronic device 100 can be enhanced.

In some embodiments, the electronic device 100 may include circuit structures CS2 and CS3 disposed on the upper surface and lower surface of the second transparent substrate SUB2, respectively. The circuit structure CS2 may include an insulation layer IL2 disposed on the upper surface of the second transparent substrate SUB2 and a wiring structure WS2 formed in the insulation layer IL2. In some embodiments, the insulation layer IL2 may include a plurality of insulation layers alternately stacked along the direction D2. In some embodiments, the wiring structure WS2 may include a plurality of conductive patterns alternately stacked along the direction D2 and formed in the insulation layer IL2, and a conductive via connecting the conductive patterns. The circuit structure CS3 may include an insulation layer IL3 disposed on the lower surface of the second transparent substrate SUB2 and a wiring structure WS3 formed in the insulation layer IL3. In some embodiments, the insulation layer IL3 may include a plurality of insulation layers alternately stacked along the direction D2. In some embodiments, the wiring structure WS3 may include a plurality of conductive patterns alternately stacked along the direction D2 and formed in the insulation layer IL3, and a conductive via connecting the conductive patterns.

The wiring structures WS2 and WS3 may each include any suitable conductive material, such as copper, titanium, nickel, combinations thereof, or alloys of the above materials, but are not limited thereto. The insulation layers IL2 and IL3 may each contain organic materials or inorganic materials. The organic materials include polyimide (PI), poly-p-xylylene (also known as Parylene), benzocyclobutene (BCB), epoxy, polycarbonate (PC), polyethylene terephthalate (PET), polyethylene naphthalate (PEN), polymers or other suitable organic materials, but the present disclosure is not limited thereto. The inorganic materials include silicon oxide, silicon nitride, silicon oxynitride or other suitable inorganic materials, but the present disclosure is not limited thereto.

The conductive element TGV22 may be electrically connected to the circuit structures CS2 and CS3, respectively. In this embodiment, the wiring structure WS2 of the circuit structure CS2 may include pads CP1 formed on the insulation layer IL2 and in contact with the connection members CE2. In this embodiment, the wiring structure WS3 of the circuit structure CS3 may include pads CP2 formed on the insulation layer IL3 and in contact with the connection members CE3. The connection members CE3 may be, for example, connection members that electrically connect the electronic device 100 to other components, elements or devices, but are not limited thereto. The connection members CE3 may include solder balls. In some embodiments, the materials of the connection members CE3 may include tin-silver (SnAg), tin, silver, nickel, gold, copper, conductive adhesive or other suitable conductive materials, but are not limited thereto.

In some embodiments, the electronic device 100 may include a first buffer layer BL1 disposed between the first transparent substrate SUB1 and the second transparent substrate SUB2 and surrounding at least one of the plurality of connection members CE2, to enhance the reliability of the electronic device 100. The first buffer layer BLI may include any suitable underfill material. In this embodiment, the description of “one element surrounding another element” may refer to the element being at least in contact with the side surface of the other element in the cross-sectional view. For example, as shown in FIG. 1, the first buffer layer BL1 may be in contact with the side surfaces of the connection members CE2. In other embodiments, the description of “one element surrounding another element” may refer to the element being adjacent to the side surface of another element in the cross-sectional view of the electronic device 100, but the present disclosure is not limited thereto.

In some embodiments, the electronic device 100 may include a second buffer layer BL2 disposed between the electronic unit EU1 or EU2 and the first transparent substrate SUB1 and surrounding at least one of the plurality of connection members CE1, to enhance the reliability of the electronic device 100. The second buffer layer BL2 may include any suitable underfill material. In this embodiment, the description of “one element surrounding another element” may refer to the element being at least in contact with the side surface of the other element in the cross-sectional view. For example, as shown in FIG. 1, the second buffer layer BL2 may be in contact with the side surfaces of the connection members CE1. In some embodiments, a particle size of a filler of the second buffer layer BL2 is smaller than a particle size of a filler of the first buffer layer BL1 for better quality, but not limited thereto.

In some embodiments, the electronic device 100 may include an encapsulation layer ML1 on the first transparent substrate SUB1 and surrounding the electronic units EU1 and EU2 and the circuit structure CS1. The encapsulation layer ML1 may prevent the electronic units EU1 and EU2 from being affected by the external moisture, thereby improving the reliability of the electronic device 100. The encapsulation layer ML1 may include any suitable encapsulation material, such as an epoxy molding compound (EMC), but is not limited thereto.

In some embodiments, the electronic device 100 may include an encapsulation layer

ML2 on the second transparent substrate SUB2 and surrounding the circuit structure CS2, the first buffer layer BLI and the encapsulation layer ML1. The encapsulation layer ML2 may be beneficial to further improve the reliability of the electronic device 100. The encapsulation layer ML2 may include any suitable encapsulation material, such as an epoxy molding compound (EMC), but is not limited thereto.

FIG. 2 is a cross-sectional schematic view of an electronic device according to another embodiment of the present disclosure. The electronic device 200 shown in FIG. 2 is similar to the electronic device 100 shown in FIG. 1. The main differences therebetween are that the electronic device 200 includes a substrate SUB3 including a printed circuit board PCB connected to the connection members CE2, and electronic units EU1 and EU3 disposed on the circuit structure CS1 and electrically connected to the conductive elements TGV1, TGV11 through the circuit structure CS1. Other identical or similar elements are represented by the same or similar reference numerals and will not be repeated hereinafter.

As shown in FIG. 2, the electronic device 200 may include an electronic unit EU3 disposed on the circuit structure CS1 and electrically connected to the conductive elements TGV1 through the circuit structure CS1. In this embodiment, the electronic unit EU3 may be a photonic integrated circuit (PIC) connected to a fiber F, but is not limited thereto. In some embodiments, the substrate SUB3 may be a printed circuit board (PCB), but the present disclosure is not limited thereto.

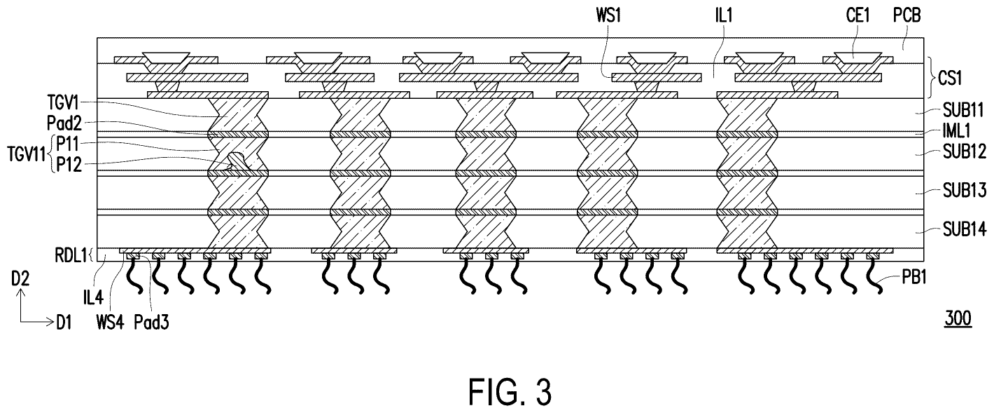

FIG. 3 is a cross-sectional schematic view of an electronic device according to yet another embodiment of the present disclosure. The electronic device 300 shown in FIG. 3 is similar to the electronic device 100 shown in FIG. 1. The main differences therebetween are that the electronic device 300 may be, for example, a probe card, which includes: substrates SUB11, SUB12, SUB13 and SUB14 stacked with each other in the direction D2; intermediate layers IML1 disposed between the substrates SUB11, SUB12, SUB13 and SUB14 and connecting the substrates SUB11, SUB 12, SUB13 and SUB 14 together; a redistribution structure RDL1 disposed on the substrate SUB14; probes PB1 disposed on the redistribution structure RDL1; and a printed circuit board PCB disposed above the transparent substrate SUB11 and electrically connected to the conductive elements TGV1 and TGV11 through the circuit structure CS1. Other identical or similar elements are represented by the same or similar reference numerals and will not be repeated hereinafter.

In this embodiment, the substrates SUB11, SUB12, SUB 13 and SUB 14 of the electronic device 300 may be bonded together through the intermediate layers IML1 disposed therebetween, so as to form a stacked substrate, such as a multi-layer organic (MLO) substrate or a multi-layer ceramic (MLC) substrate, but is not limited thereto. In this embodiment, the substrates SUB11, SUB12, SUB13 and SUB 14 may include any suitable substrate material, such as glass substrates. In some alternative embodiments, the intermediate layers IML1 may include any suitable adhesive material. The conductive elements TGV1 and TGV11 in the substrates SUB11, SUB12, SUB13 and SUB14 may be electrically connected to each other through pads Pad2 disposed in the intermediate layers IML1, but is not limited thereto. In some embodiments, the intermediate layers IML1 may include anisotropic conductive film (ACF), anisotropic conductive paste (ACP), or other conductive anisotropic conductive bonding members. In this embodiment, as the intermediate layers IML1 may be anisotropic conductive bonding members in which the electrical connections are conducted in the direction D2 instead of in the direction D1, the pads Pad2 in the intermediate layers IML1 may be omitted optionally. The pad Pad2 may include any suitable conductive material, such as copper (Cu), aluminum (Al), nickel (Ni), molybdenum (Mo), titanium (Ti), alloys or combinations of the above materials, or other suitable materials, but is not limited thereto.

In this embodiment, the printed circuit board PCB of the electronic device 300 may be disposed above the transparent substrate SUB11 and electrically connected to the conductive elements TGV1 and TGV11 of the transparent substrate SUB11 through the circuit structure CS1 and the connection members CE1 between the printed circuit board PCB and the transparent substrate SUB11. In this embodiment, the repaired conductive element TGV11 according to the above-mentioned embodiment may be disposed in any one of the substrates SUB11, SUB12, SUB13 and SUB14. For example, in this embodiment, the conductive element TGV11 is formed in the substrate SUB12.

In this embodiment, the redistribution structure RDL1 of the electronic device 300 may be disposed on the surface of the substrate SUB14 away from the substrate SUB13 and may include an insulation layer IL4 and a wiring structure WS4. In some alternative embodiments, the insulation layer IL4 may include a plurality of insulation layers alternately stacked along the direction D2. In some alternative embodiments, the wiring structure WS4 may include a plurality of conductive patterns formed in the insulation layer IL4 and alternately stacked along the direction D2, and a conductive via connecting the conductive patterns. The redistribution structure RDL1 may be able to redistribute the wirings and/or to increase the fan-out area of the wirings, or different electronic elements may be electrically connected to each other through the redistribution structure. The method for forming the redistribution structure may include providing a stack of at least one insulation layer and at least one conductive layer and may include processes such as a photolithography process, an etching process, a surface treatment, a laser process, and an electroplating process. The surface treatment includes roughening the surface of the insulation layer or the conductive layer to enhance its adhesion ability. Alternatively, the redistribution structure may be used as a substrate for electrical interface wiring between one connection and another connection. The purpose of the redistribution structure is to extend the connections to wider pitches or redistribute the connections to another connection with different pitches. The insulation layer IL4 may include polyimide (PI), photosensitive polyimide (PSPI), polybenzoxazole (PBO), epoxy resin, Ajinomoto Build-up Film (ABF), silicon oxide (SiOₓ), silicon nitride (SiNₓ), any other suitable insulation material, or a combination of the above materials, but is not limited thereto. The wiring structure WS4 may include any suitable conductive material, such as copper, titanium, nickel, a combination thereof, or alloy of the above materials, but is not limited thereto. In this disclosure, the circuit structure CS1, the circuit structure CS2, and the circuit structure CS3 may all be redistribution structures, but the present disclosure is not limited thereto.

In this embodiment, the probes PB1 of the electronic device 300 may be disposed on the redistribution structure RDL1 and electrically connected to the conductive elements TGV1 and TGV11 in the substrates SUB11, SUB12, SUB13 and SUB 14 through the redistribution structure RDL1. The ones of ends of the probes PB1 may contact the pads Pad3 disposed on the wiring structures WS4, and other ones of ends of the probes PB1 may protrude from the insulation layer IL4 to contact the target to be measured. The pads Pad3 may include any suitable conductive material, such as copper (Cu), aluminum (Al), nickel (Ni), molybdenum (Mo), titanium (Ti), alloys or combinations of the above materials, or other suitable materials, but is not limited thereto. In some embodiments, the probes PB1 may be, for example, conductive probes including any suitable conductive materials.

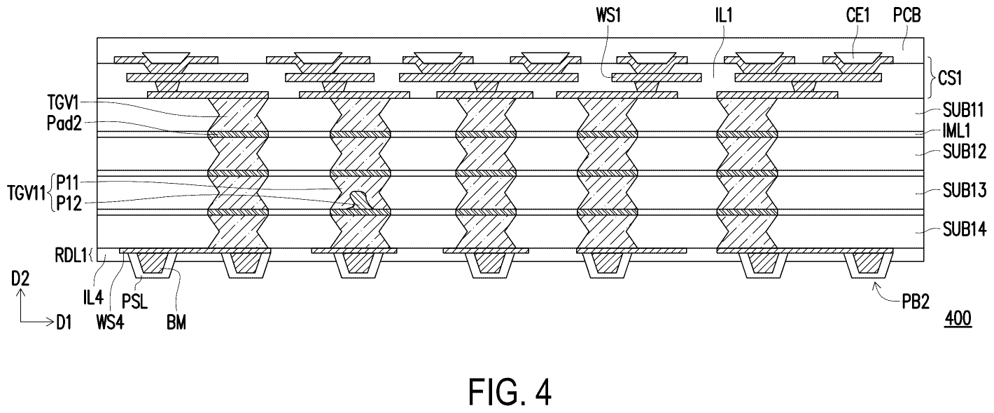

FIG. 4 is a cross-sectional schematic view of an electronic device according to still another embodiment of the present disclosure. The electronic device 400 shown in FIG. 4 is similar to the electronic device 300 shown in FIG. 3. The main difference is that the probes PB2 of the electronic device 400 are different from the probes PB1 of the electronic device 300. Other identical or similar elements are represented by the same or similar reference numerals and will not be repeated hereinafter.

In this embodiment, the probes PB2 of the electronic device 400 may include conductive bumps BM formed on the wiring structures WS4 of the redistribution structure RDL1 and protruding from the insulation layer IL4, and passivation layer PSL covering the surfaces of the conductive bumps BM. The conductive bumps BM may include any suitable conductive materials, such as copper (Cu), aluminum (Al), nickel (Ni), molybdenum (Mo), titanium (Ti), alloys or combinations of the above materials, or other suitable materials, but are not limited thereto. The passivation layers PSL may be, for example, passivation layers capable of preventing surface oxidation. The passivation layers may include nitrogen-containing conductive materials such as titanium nitride (TiN), but are not limited thereto.

In this embodiment, the probes PB2 of the electronic device 400 may be electrically connected to the conductive elements TGV1 and TGV11 in the substrates SUB11, SUB12, SUB13 and SUB14 through the redistribution structure RDL1. In this embodiment, the conductive element TGV11 repaired by the above embodiment may be disposed in any one of the substrates

SUB11, SUB12, SUB13 and SUB14. For example, in this embodiment, the conductive element TGV11 is formed in the substrate SUB13. Ones of ends of the probes PB2 may contact the wiring structure WS4, and the other ones of ends of the probes PB2 may contact the target to be measured through the passivation layers PSL covering the surfaces of the probes PB2.

In summary, in the electronic device and the method for manufacturing the same according to the embodiments of this disclosure, the defect regions are identified from the through holes among which the conductive elements formed therein having defects such as voids, and then the repair process is performed on the defect regions, so that the conductive elements are repaired to include a first portion and a second portion surrounded by the first portion, wherein the surface of the first portion has protrusions and recesses, and at least a portion of the second portion is disposed in at least one of recesses. As such, the defects of the conductive elements in the defect regions can be repaired, so there are no negative effects on the resistivity of the conductive element caused by the defects, and thus the reliability of the electronic device can be improved.

The above embodiments are used to describe the technical solution of the disclosure and are not a limitation thereof. Although the disclosure has been described in detail with reference to each embodiment above, those having ordinary skill in the art should understand that the technical solution recited in each embodiment above may still be modified, or some or all of the technical features thereof may be equivalently replaced. These modifications or replacements do not make the essence of the corresponding technical solutions depart from the scope of the technical solution of each embodiment of the disclosure.

Although the embodiments of the disclosure and their advantages are disclosed as above, it should be understood that any person with ordinary skill in the art, without departing from the spirit and scope of the disclosure, may make changes, substitutions, and modifications, and features between the embodiments may be mixed and replaced at will to form other new embodiments. In addition, the scope of the disclosure is not limited to the manufacturing processes, machines, manufactures, material compositions, devices, methods, and steps in the specific embodiments described in the specification. Any person with ordinary skill in the art may understand the current or future development processes, machines, manufactures, material compositions, devices, methods, and steps from the content of the disclosure, which may all be adopted according to the disclosure as long as they may implement substantially the same function or obtain substantially the same result in an embodiment described here. Therefore, the scope of the disclosure includes the above manufacturing processes, machines, manufactures, material compositions, devices, methods, and steps. In addition, each claim constitutes an individual embodiment, and the scope of the disclosure also includes the combination of each claim and embodiment. The scope of the disclosure shall be subject to the scope defined by the following claims.

What is claimed is:

1. An electronic device, comprising:
a first transparent substrate having a plurality of through holes;
a conductive element disposed in at least one of the plurality of through holes, wherein the conductive element comprises a first portion and a second portion, and the first portion surrounds the second portion;
a circuit structure disposed on the first transparent substrate; and
an electronic unit disposed on the circuit structure and electrically connected to the conductive element through the circuit structure,
wherein a surface of the first portion of the conductive element has a plurality of recesses, and at least a portion of the second portion of the conductive element is disposed in at least one of the plurality of recesses.

2. The electronic device according to claim 1, wherein a roughness of the surface of the first portion of the conductive element is less than 1 um.

3. The electronic device according to claim 1, wherein the second portion of the conductive element comprises a conductive material and an insulation material, a proportion of the conductive material contacting the first portion is greater than a proportion of the insulation material contacting the first portion.

4. The electronic device according to claim 1, wherein a resistivity of the first portion of the conductive element is different from a resistivity of the second portion of the conductive element.

5. The electronic device according to claim 1, further comprising:
a second transparent substrate, wherein the first transparent substrate is bonded to the second transparent substrate through a plurality of first connection members.

6. The electronic device according to claim 5, wherein the second portion of the conductive element contacts one of the plurality of first connection members.

7. The electronic device according to claim 5, wherein a thickness of the second transparent substrate is greater than a thickness of the first transparent substrate.

8. The electronic device according to claim 5, further comprising:
a first buffer layer disposed between the first transparent substrate and the second transparent substrate and surrounding at least one of the plurality of first connection members.

9. The electronic device according to claim 8, further comprising:
a second buffer layer disposed between the electronic unit and the first transparent substrate.

10. The electronic device according to claim 1, further comprising:
a protective layer disposed on a surface of the at least one of the plurality of through holes.

11. The electronic device according to claim 10, wherein a width of the protective layer covering a surface of the first transparent substrate is greater than or equal to half of a depth of the at least one of the plurality of through hole.

12. The electronic device according to claim 10, wherein a ratio of a toughness of the protective layer to a toughness of a dielectric layer comprised in the circuit structure is greater than or equal to 0.1 and less than or equal to 10.

13. A method for manufacturing an electronic device, comprising:
providing a transparent substrate;
forming a plurality of through holes in the transparent substrate; and
providing a conductive element in at least one of the plurality of through holes, comprising:
providing a first portion of the conductive element in the at least one of the plurality of through holes;
identifying the first portion of the conductive element to obtain a result whether the first portion of the conductive element has a defect region;
checking the result and performing a treatment on the defect region if the result shows that the first portion of the conductive element has the defect region; and
providing a second portion of the conductive element on the defect region to form the conductive element.

14. The method according to claim 13, wherein the first portion of the conductive element is electrically connected to the second portion of the conductive element.

15. The method according to claim 13, wherein a step of performing the treatment on the defect region comprises removing at least a portion of the first portion of the conductive element as the result shows that the first portion of the conductive element has the defect region.

16. The method according to claim 15, wherein a step of removing at least the portion of the first portion of the conductive element comprises a laser drill process, a mechanical drill process, an etching process, or a combination thereof.

17. The method according to claim 15, wherein a surface of the first portion of the conductive element has a plurality of recesses in a case where at least the portion of the first portion of the conductive element has been removed, and the second portion of the conductive element is formed in at least one of the plurality of recesses.

18. The method according to claim 17, wherein a roughness of the surface is less than 1 μm.

19. The method according to claim 13, wherein a resistivity of the second portion of the conductive element conductive element is different from a resistivity of the first portion of the conductive element.

20. The method according to claim 14, wherein the second portion of the conductive element comprises a conductive material and an insulation material, and a proportion of the first portion of the conductive element contacting the conductive material is greater than a proportion of the first portion of the conductive element contacting the insulation material.
